(19) United States
(12) Patent Application Publication
(10) Pub. No.: US 2021/0271841 A1
(43) Pub. Date: Sep. 2, 2021

(54) ELECTRONIC DEVICE

(71) Applicant: Egis Technology Inc., Taipei (TW)

(72) Inventors: PIN-YU CHEN, Taipei City (TW); TONG-LONG FU, Taipei City (TW); CHEN-CHIH FAN, Taipei City (TW)

(21) Appl. No.: 17/258,259

(22) PCT Filed: Oct. 18, 2019
(86) PCT No.: PCT/CN2019/111892

§ 371 Date: Jan. 6, 2021

Related U.S. Application Data
(63) Continuation of application No. 62/848,069, filed on May 15, 2019.
Application No. 62/848,069 is a continuation of application No. 62/799,275, filed on Jan. 31, 2019.
Application No. 62/799,275 is a continuation of application No. 62/771,251, filed on Nov. 26, 2018.

(51) Int. Cl. G06K 9/00

(52) U.S. Cl. CPC G06K 9/0002; G06K 9/0004; G06K 9/00087

(57) ABSTRACT

The present invention relates to an electronic device with a lens supporting element. The electronic device includes a display screen, an intermediate frame, a lens supporting element, an interface structure and a base structure. The intermediate frame has a frame hollow region. A fingerprint sensing unit is installed on the lens supporting element. The fingerprint sensing unit is located near the frame hollow region through the lens supporting element. The interface structure is arranged between the intermediate frame and the lens supporting element, and/or arranged between the lens supporting element and the base frame. Consequently, the lens supporting element is positioned in or clamped between the intermediate frame and the base structure through the interface structure.

### FIELD OF THE INVENTION

The present invention relates to an electronic device with a lens supporting element, and more particularly to an electronic device with a lens supporting element that is installed through an interface structure and/or a fastening member.

### BACKGROUND OF THE INVENTION

With the maturity of modern fingerprint sensing technologies, lens supporting elements and fingerprint sensing units are widely used in electronic devices or products. Various fingerprint sensing technologies such as capacitive, optical and ultrasonic sensing technologies are being continuously developed. So far, the capacitive fingerprint recognition technology and the optical fingerprint recognition technology are more feasible for commercialization.

Take the under-display fingerprint identification technology for example. The structural design of a lens supporting element and the method of assembling the lens supporting element with a display screen, an intermediate frame and a base structure are usually the key factors influencing the overall product yield and the fabricating cost.

For example, a fingerprint sensing unit is usually disposed within the lens supporting element or located at a lower part of the lens supporting element. In accordance with the conventional assembling method, the lens supporting element is in direct contact with the bottom of the intermediate frame. However, the assembling method is complicated, the operation of the fingerprint sensing unit is adversely affected, or the cost is not effective. For example, since the lens supporting element is in direct contact with the bottom of the intermediate frame, the associated components are readily damaged because of collision. Consequently, the quality of the fingerprint sensing unit within the lens supporting element is impaired. Moreover, since the lens supporting element is directly contacted with the intermediate frame and assembled with the intermediate frame, the thermal effect of the display screen may adversely influence the operation of the fingerprint sensing unit. In some other words, the conventional technologies need to be further improved.

For overcoming the drawbacks of the conventional technologies, the present invention provides a novel electronic device and a method of installing a lens supporting element of the electronic device in order to effectively reduce the overall thickness of the electronic device with the lens supporting element.

### SUMMARY OF THE INVENTION

An object of the present invention provides an electronic device with a lens supporting element. The lens supporting element is arranged between the intermediate frame and a base structure through an interface structure. Consequently, a fingerprint sensing unit disposed within the lens supporting element or located at a lower part of the lens supporting element can sense a fingerprint signal from a display screen.

A first embodiment of the present invention provides an electronic device. The electronic device includes a display screen, an intermediate frame, a lens supporting element, an interface structure and a base structure. The intermediate frame includes a frame hollow region. The intermediate frame is located beside a side of the display screen. A fingerprint sensing unit is installed on the lens supporting element. The fingerprint sensing unit is located near the frame hollow region and located beside the side of the display screen through the lens supporting element. The lens supporting element is disposed on the base structure. The interface structure is arranged between the lens supporting element and one of the display screen and the intermediate frame, and/or the interface structure is arranged between the lens supporting element and the base structure.

Preferably, the lens supporting element includes a lens barrel and a supporting structure. The lens barrel is arranged between an upper part of the supporting structure and the frame hollow region. The interface structure is arranged between the supporting structure and one of the display screen and the intermediate frame and/or arranged between the supporting structure and the base structure.

Preferably, the lens supporting element includes an integral structure of a lens barrel and a supporting structure. The lens supporting element is adhered on the intermediate frame or the base structure, indirectly contacted with the intermediate frame or the base structure or clamped between the intermediate frame and the base structure through the upper part or a lower part of the supporting structure and the interface structure.

Preferably, the interface structure is one of a glue structure, an elastic structure, an injection molding structure and a fastening member.

Preferably, the injection molding structure is a hot melt post, and the lens supporting element is installed on the base structure through the hot melt post.

Preferably, the fastening member includes an iron element and a screw. The iron element is combined with the lens supporting element. The screw is penetrated through one of the iron element and the supporting structure. Consequently, the supporting structure is fixed on the base structure.

Preferably, the interface structure includes a first interface part and a second interface part. The first interface part is located near the lens barrel and arranged between the supporting structure and one of the display screen and the intermediate frame. The second interface part is arranged between the supporting structure and the base structure.

Preferably, the first interface part is one of a light-shielding structure and a glue structure, and the second interface part is one of a glue structure, an elastic structure, an injection molding structure and a fastening member.

Preferably, the injection molding structure is a hot melt post, and the supporting structure is installed on the base structure through the hot melt post.

Preferably, the fastening member includes an iron element and a screw. The iron element is combined with the supporting structure. The screw is penetrated through one of the iron element and the supporting structure. Consequently, the supporting structure is fixed on the base structure.

Preferably, the supporting structure is adhered on the intermediate frame or the base structure, indirectly contacted with the intermediate frame or the base structure or clamped between the intermediate frame and the base structure through the upper part or a lower part of the supporting structure and the interface structure.

Preferably, the lens barrel and the supporting structure are combined together in a threaded engaging manner, a locking manner or an embedding manner. The supporting structure is adhered on or indirectly contacted with the base structure through the interface structure.

Preferably, the interface structure includes a first interface part and a second interface part. The first interface part is located near the lens barrel and arranged between the supporting structure and one of the display screen and the intermediate frame. The second interface part is arranged between the supporting structure and the base structure.

Preferably, the first interface part is one of a light-shielding structure and a glue structure, and the second interface part is one of a glue structure, an elastic structure, an injection molding structure and a fastening member.

Preferably, the injection molding structure is a hot melt post, and the supporting structure is installed on the base structure through the hot melt post.

Preferably, the fastening member includes an iron element and a screw. The iron element is combined with the supporting structure. The screw is penetrated through one of the iron element and the supporting structure. Consequently, the supporting structure is fixed on the base structure.

Preferably, the interface structure includes a first interface part and a second interface part. The lens barrel is positioned in the frame hollow region through the first interface part. The second interface part is arranged between the supporting structure and the base structure.

Preferably, the first interface part is one of a light-shielding structure and a glue structure, and the second interface part is one of a glue structure, an elastic structure, an injection molding structure and a fastening member.

Preferably, the injection molding structure is a hot melt post, and the supporting structure is installed on the base structure through the hot melt post.

Preferably, the fastening member includes an iron element and a screw. The iron element is combined with the supporting structure. The screw is penetrated through one of the iron element and the supporting structure. Consequently, the supporting structure is fixed on the base structure.

Preferably, one of the intermediate frame and the base structure includes a concave region, and a portion of the lens supporting element is received within the concave region.

Preferably, the base structure is one of a circuit board, a chassis and a battery

Preferably, the interface structure includes a first interface part and a second interface part. The first interface part is located near the lens barrel and arranged between the lens supporting element and one of the display screen and the intermediate frame. The second interface part is arranged between the lens supporting element and the base structure

Preferably, the first interface part is one of a light-shielding structure and a glue structure, and the second interface part is one of a glue structure, an elastic structure, an injection molding structure and a fastening member.

Preferably, the injection molding structure is a hot melt post, and the lens supporting element is installed on the base structure through the hot melt post.

Preferably, the fastening member includes an iron element and a screw. The iron element is combined with the lens supporting element. The screw is penetrated through one of the iron element and the lens supporting element. Consequently, the lens supporting element is fixed on the base structure.

A second embodiment of the present invention provides an electronic device. The electronic device includes a display screen, an intermediate frame, a lens supporting element, a fastening member and a base structure. The intermediate frame includes a frame hollow region. The intermediate frame is located beside a side of the display screen. A fingerprint sensing unit is installed on the lens supporting element. The fingerprint sensing unit is located near the frame hollow region and located beside the side of the display screen through the lens supporting element. The base structure is located under the lens supporting element. The lens supporting element is indirectly installed on one of the intermediate frame and the base structure through the fastening member.

Preferably, the fastening member is arranged between one of the intermediate frame and the base structure and the lens supporting element, or the lens supporting element is received within the fastening member and combined with one of the intermediate frame and the base structure.

Preferably, the fastening member includes an iron element and a screw. The iron element is combined with the lens supporting element. The screw is penetrated through one of the iron element and the lens supporting element. Consequently, the lens supporting element is fixed on one of the intermediate frame and the base structure.

Preferably, the lens supporting element includes a lens barrel and a supporting structure. The lens barrel is arranged between an upper part of the supporting structure and the frame hollow region. The supporting structure is installed on one of the intermediate frame and the base structure through the fastening member.

Preferably, the lens supporting element includes a two-piece structure of the lens barrel and the supporting structure, or the lens supporting element includes an integral structure of the lens barrel and the supporting structure.

Preferably, the electronic device further includes an interface part. The interface part is arranged between the lens supporting element and one of the display screen and the intermediate frame, and/or the interface part is arranged between the lens supporting element and the base structure.

Preferably, the interface part is one of a glue structure, an elastic structure and an injection molding structure.

A third embodiment of the present invention provides an electronic device. The electronic device includes a display screen, an intermediate frame, a lens supporting element, a fastening member, an interface part and a base structure. The intermediate frame includes a frame hollow region. The intermediate frame is located beside a side of the display screen. The fingerprint sensing unit is installed on the lens supporting element. The fingerprint sensing unit is located near the frame hollow region and located beside the side of the display screen through the lens supporting element. The base structure is located under the lens supporting element. The lens supporting element is indirectly installed on the intermediate frame through the fastening member. The interface part is arranged between the lens supporting element and the base structure.

Preferably, the fastening member includes an iron element and a screw. The iron element is combined with the lens supporting element. The screw is penetrated through one of the iron element and the lens supporting element. Consequently, the lens supporting element is fixed on the intermediate frame.

Preferably, the fastening member is arranged between the intermediate frame and the lens supporting element, or the lens supporting element is received within the fastening member and then combined with the intermediate frame.

Preferably, the lens supporting element includes a lens barrel and a supporting structure. The lens barrel is arranged between an upper part of the supporting structure and the frame hollow region. The supporting structure is indirectly installed on the intermediate frame through the fastening member.

Preferably, the interface part is one of a glue structure, an elastic structure and an injection molding structure.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic exploded view illustrating the indirect installation of a lens supporting element on a base structure through an interface structure according to a first embodiment of the present invention;

FIG. 1B is a schematic cross-sectional view illustrating the assembled structure as shown in FIG. 1A;

FIG. 1C is a schematic cross-sectional view illustrating the lens supporting element of the assembled structure as shown in FIG. 1B;

FIGS. 2A and 2B are schematic perspective views illustrating two examples of the lower part of the supporting structure of the lens supporting element;

FIG. 3A is a schematic exploded view illustrating the indirect installation of a lens supporting element on a base structure through an interface structure according to a second embodiment of the present invention;

FIG. 3B is a schematic cross-sectional view illustrating the assembled structure as shown in FIG. 3A;

FIG. 3C is a schematic cross-sectional view illustrating the lens supporting element of the assembled structure as shown in FIG. 3B;

FIG. 4A is a schematic exploded view illustrating the indirect installation of a lens supporting element on a base structure through an interface structure according to a third embodiment of the present invention;

FIG. 4B is a schematic cross-sectional view illustrating the assembled structure as shown in FIG. 4A;

FIG. 4C is a schematic cross-sectional view illustrating the lens supporting element of the assembled structure as shown in FIG. 4B;

FIG. 5 is a schematic cross-sectional view illustrating the indirect installation of a lens supporting element on a base structure through an interface structure according to a fourth embodiment of the present invention;

FIG. 6 is a schematic cross-sectional view illustrating the indirect installation of a lens supporting element on a base structure through an interface structure according to a fifth embodiment of the present invention;

FIG. 7A is a schematic exploded view illustrating the indirect installation of a lens supporting element on an intermediate frame through an interface structure according to a first embodiment of the present invention;

FIG. 7B is a schematic perspective view illustrating the assembled structure as shown in FIG. 7A;

FIG. 7C is a schematic cross-sectional view illustrating the electronic device as shown in FIG. 7B;

FIG. 8A is a schematic exploded view illustrating the indirect installation of a lens supporting element on an intermediate frame through an interface structure according to a second embodiment of the present invention;

FIG. 8B is a schematic perspective view illustrating the assembled structure as shown in FIG. 8A;

FIG. 8C is a schematic cross-sectional view illustrating the electronic device as shown in FIG. 8B;

FIG. 9A is a schematic exploded view illustrating the indirect installation of a lens supporting element on an intermediate frame through an interface structure according to a third embodiment of the present invention;

FIG. 9B is a schematic perspective view illustrating the assembled structure as shown in FIG. 9A; and

FIG. 9C is a schematic cross-sectional view illustrating the electronic device as shown in FIG. 9B.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

For overcoming the drawbacks of the conventional technologies, the present invention provides a novel assembling design of an electronic device. According to the assembling design, a lens supporting element is indirectly assembled and installed in a region between an intermediate frame and a base structure through an interface structure. Especially, when the accuracy of assembling the lens supporting element and the influence of the thermal effect of the display screen on a fingerprint sensing unit within or under the lens supporting element are taken into the consideration, eight embodiments will be described as follows.

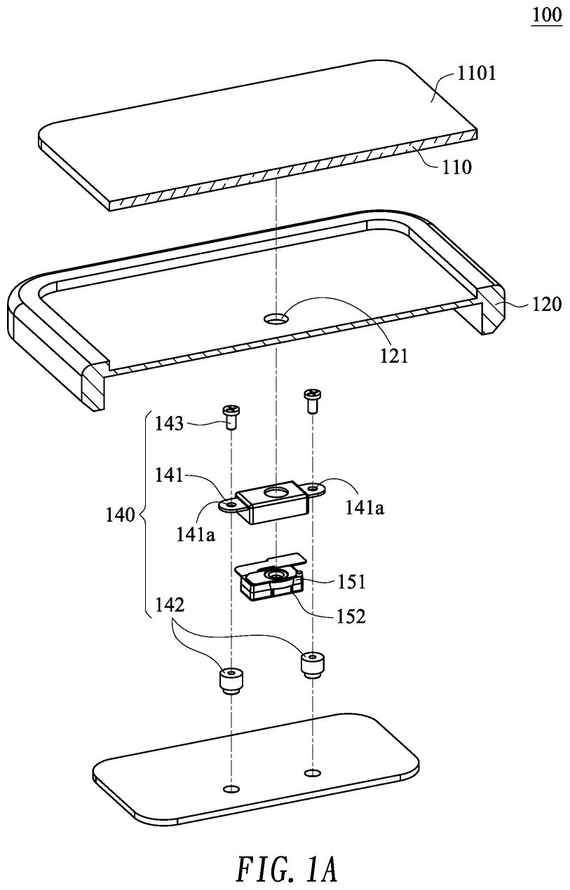

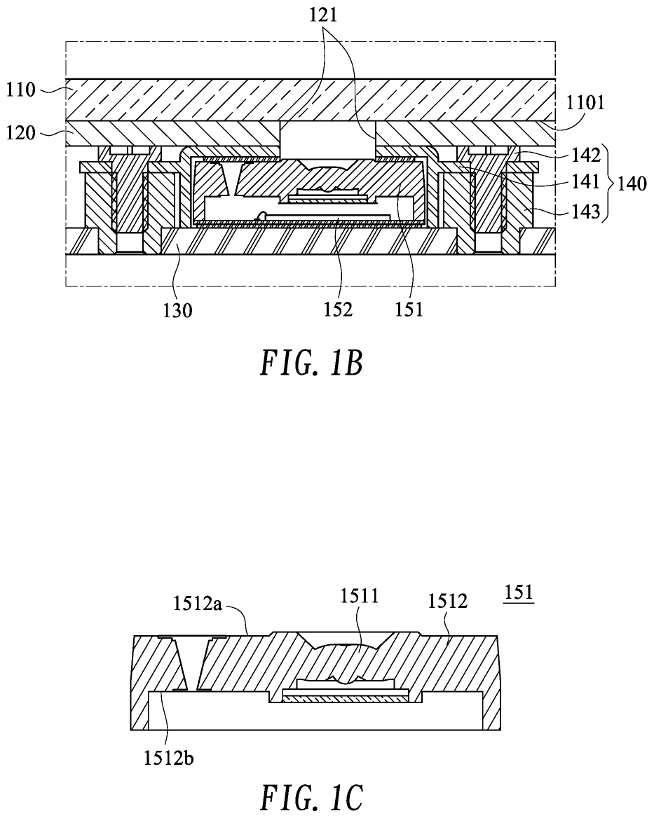

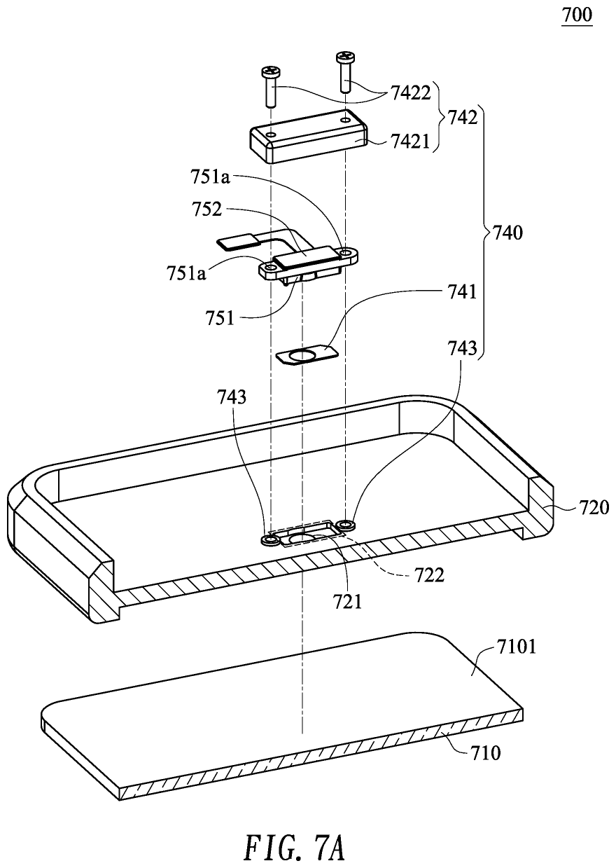

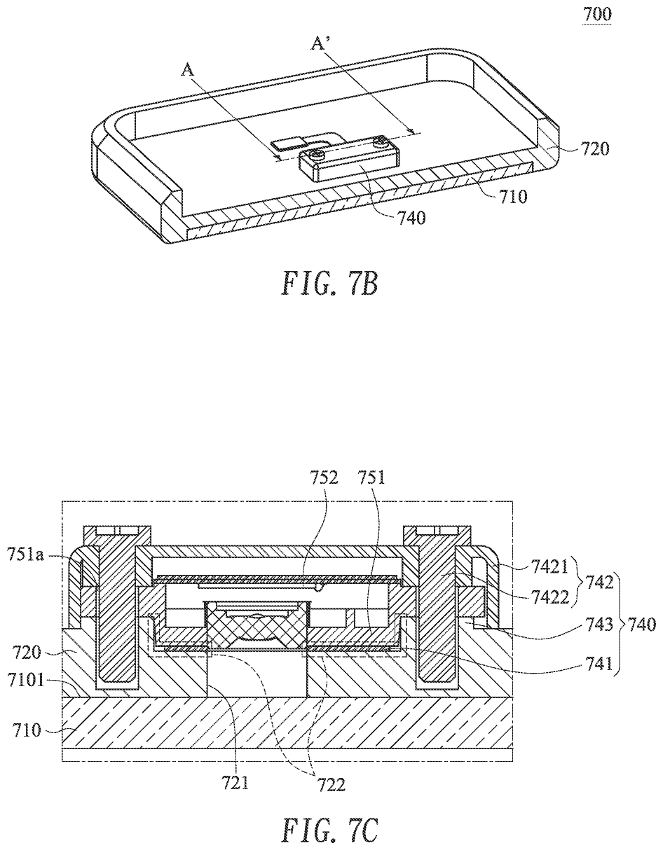

In the embodiments of FIG. 1A to FIG. 6, the lens supporting element is indirectly installed on the base structure through the interface structure, or the lens supporting element is arranged between the intermediate frame and the base structure. In the embodiments of FIG. 7A to FIG. 9C, the lens supporting element is indirectly installed on the intermediate frame through a fastening member.

FIG. 1A is a schematic exploded view illustrating the indirect installation of a lens supporting element on a base structure through an interface structure according to a first embodiment of the present invention. FIG. 1B is a schematic cross-sectional view illustrating the assembled structure as shown in FIG. 1A. FIG. 1C is a schematic cross-sectional view illustrating the lens supporting element of the assembled structure as shown in FIG. 1B. As shown in FIGS. 1A to 1C, the electronic device 100 includes a display screen 110, an intermediate frame 120, a base structure 130, an interface structure 140, a lens supporting element 151 and a fingerprint sensing unit 152. The intermediate frame 120 includes a frame hollow region 121. An example of the interface structure 140 is a fastening member 140. The fastening member 140 includes an iron element 141 with screw holes 141a, screws 142 and a position-limiting element 143. An example of the position-limiting element 143 is a nut structure 143 or a coupling structure 143. The lens supporting element 151 includes an integral structure of a lens barrel 1511 and a supporting structure 1512. The lens barrel 1511 is installed in an upper part 1512a of the supporting structure 1512. In addition, the lens barrel 1511 is located near or disposed within the frame hollow region 121. The fingerprint sensing unit 152 is disposed within the supporting structure 1512 or located at a lower part 1512b of the supporting structure 1512. The fingerprint sensing unit 152 is used for sensing a fingerprint signal from the display screen 110. It is noted that the lens supporting element 151 is not restricted to the integral structure. Other examples of the lens supporting element 151 will be described as follows.

The associated components will be described in more details. As shown in FIG. 1B, the display screen 110 is located at the topmost position of the electronic device 100. From top to bottom, the intermediate frame 120, the fastening member 140, the lens supporting element 151, the fingerprint sensing unit 152 and the base structure 130 are sequentially arranged. The intermediate frame 120 is combined with the display screen 110 and located beside a side 1101 of the display screen 110. The lens supporting element 151 and the fingerprint sensing unit 152 are assembled with the base structure 130. An assembling method will be described as follows. Firstly, the lens supporting element 151 and the fingerprint sensing unit 152 are covered or received by the iron element 141. Then, the screw 142 is penetrated through the screw hole 141a of the iron element 141, and thus the lens supporting element 151 and the fingerprint sensing unit 152 are positioned within the iron element 141. Then, the screw 142 is tightened in the nut structure 143 or the coupling structure 143, and the iron element 141 is fixed or locked on the base structure 130. Afterwards, the above resulting structure is combined with the intermediate frame 120 and the display screen 110. Consequently, the lens supporting element 151 and the fingerprint sensing unit 152 are located near the frame hollow region 121, and the lens barrel 1511 is located near or disposed within the frame hollow region 121. Since the lens supporting element 151 and the fingerprint sensing unit 152 are separated from the intermediate frame 120, the thermal effect of the display screen 110 will not directly influence the operation of the fingerprint sensing unit 152.

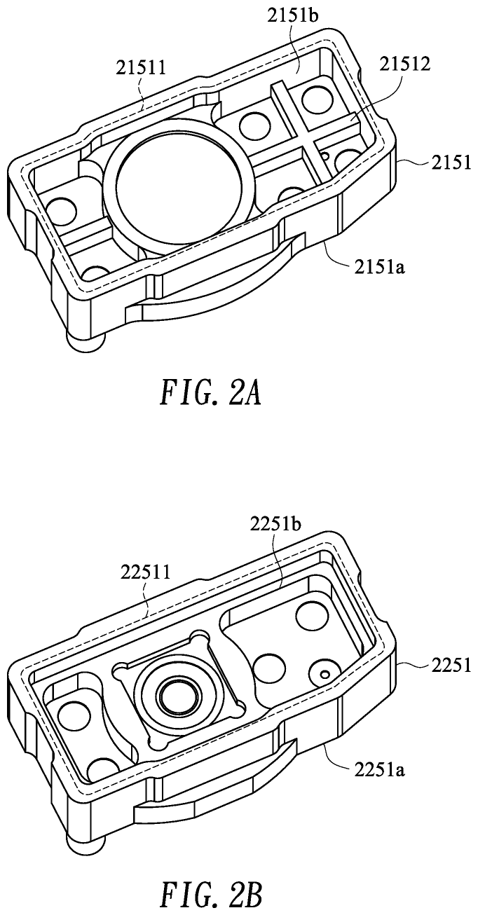

In accordance with the present invention, the lower part of the supporting structure is specially designed. The example of the supporting structure may be varied according to the practical requirements. FIGS. 2A and 2B are schematic perspective views illustrating two examples of the lower part of the supporting structure of the lens supporting element.

As shown in FIG. 2A, the upper part 2151a and the lower part 2151b of the supporting structure 2151 are located at two opposite side. The lens barrel (not shown) is installed in the upper part 2151a. The lower part 2151b includes an accommodation space 21511 and a structural post 21512. The accommodation space 21511 is defined according to the shape of the supporting structure 2151. Some electronic components (e.g., a sensor die such as the fingerprint sensing unit) are accommodated within the accommodation space 21511. The structural post 21512 is a cross-shaped structural body. Due to the structural post 21512, the stress shrinkage caused by the plastic injection molding process can be avoided. It is noted that the structural post in the lower part of the supporting structure may be omitted or modified according to the practical requirements. Another example will be described as follows.

As shown in FIG. 2B, the upper part 2251a and the lower part 2251b of the supporting structure 2251 are located at two opposite side. The lens barrel (not shown) is installed in the upper part 2251a. The lower part 2251b includes an accommodation space 22511. In comparison with the above example, the lower part 2251b is designed according to the allowable volume and number of the electronic components and the available space. In other words, the lower part 2251b is not equipped with the structural post. Since the lower part is designed according to the electronic components to be accommodated within the accommodation space, the applications are expanded.

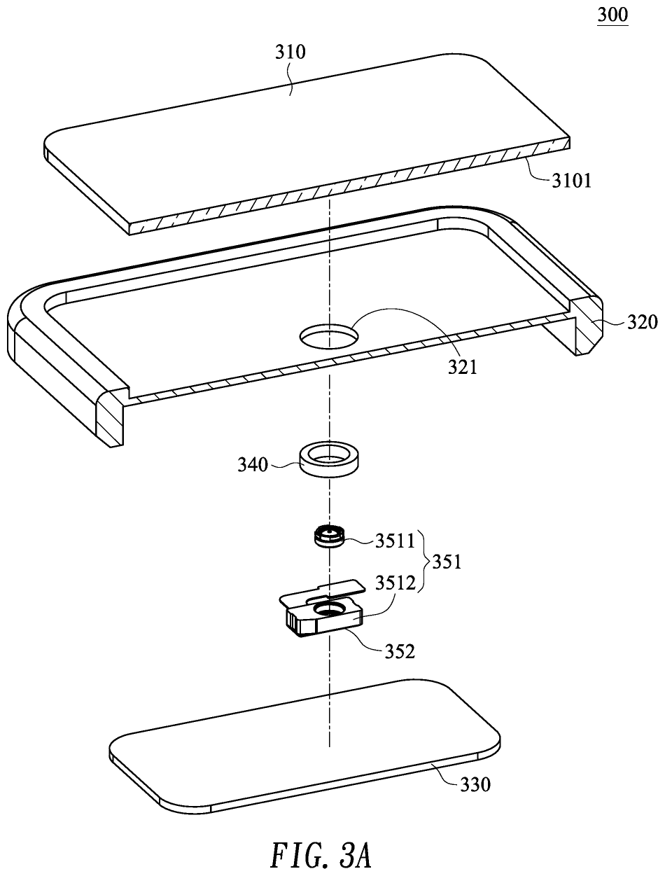

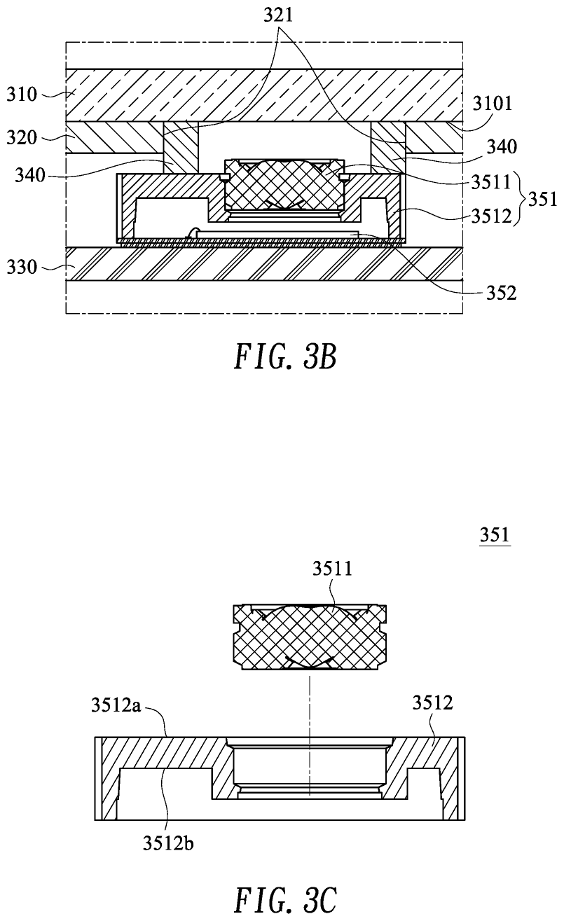

FIG. 3A is a schematic exploded view illustrating the indirect installation of a lens supporting element on a base structure through an interface structure according to a second embodiment of the present invention. FIG. 3B is a schematic cross-sectional view illustrating the assembled structure as shown in FIG. 3A. FIG. 3C is a schematic cross-sectional view illustrating the lens supporting element of the assembled structure as shown in FIG. 3B. As shown in FIGS. 3A to 3C, the electronic device 300 includes a display screen 310, an intermediate frame 320, a base structure 330, an interface structure 340, a lens supporting element 351 and a fingerprint sensing unit 352. The intermediate frame 320 includes a frame hollow region 321. An example of the interface structure 340 is a light-shielding structure 340 such as a foam structure 340. The lens supporting element 351 includes a two-piece structure of an unthreaded lens barrel 3511 and an unthreaded supporting structure 3512. According to the structural design, the lens barrel 3511 and the supporting structure 3512 match each other. Consequently, the lens barrel 3511 can be positioned in an upper part 3512a of the supporting structure 3512 in a locking manner or an embedding manner. The fingerprint sensing unit 352 is disposed within the supporting structure 3512 or located at a lower part 3512b of the supporting structure 3512.

The associated components will be described in more details. As shown in FIGS. 3A and 3B, the display screen 310 is located at the topmost position of the electronic device 300. From top to bottom, the intermediate frame 320, the fastening member 340, the lens supporting element 351, the fingerprint sensing unit 352 and the base structure 330 are sequentially arranged. The intermediate frame 320 is combined with the display screen 310 and located beside a side 3101 of the display screen 310. The foam structure 340 is disposed on the upper part 3512a of the supporting structure 3512. Moreover, the foam structure 340 is penetrated through the frame hollow region 310 and contacted with the display screen 310. Consequently, the lens supporting element 351 and the fingerprint sensing unit 352 are indirectly positioned in the region between the intermediate frame 320 and the base structure 330, and the lens barrel 3511 is located near or disposed within the frame hollow region 321. That is, the foam structure 340 may be locked on the outer periphery (not shown) of the frame hollow region 321, or contacted with the one of the display screen 310 and the intermediate frame 320. Consequently, lens supporting element 351 and the fingerprint sensing unit 352 are indirectly positioned in the region between the intermediate frame 320 and the base structure 330 without being contacted with the intermediate frame 320.

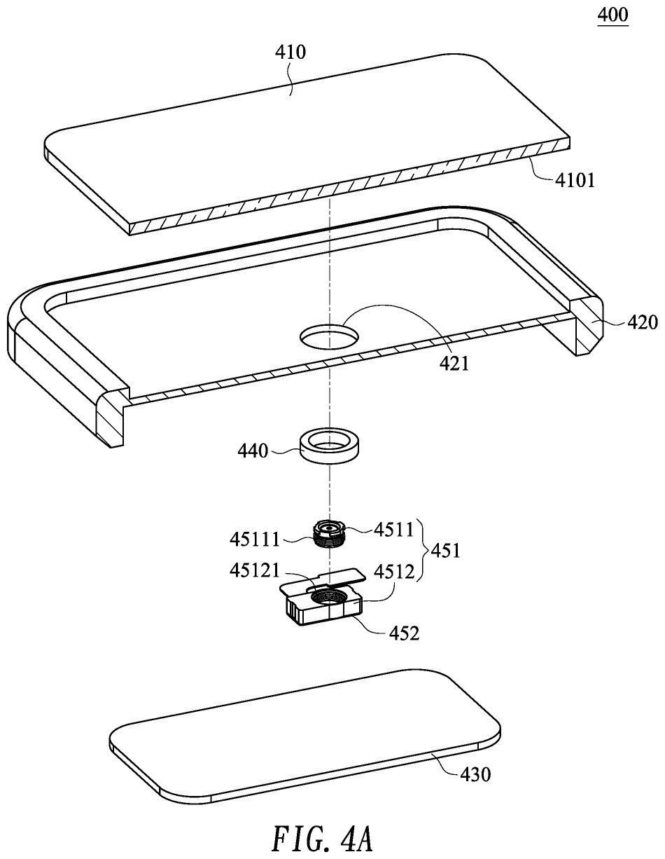

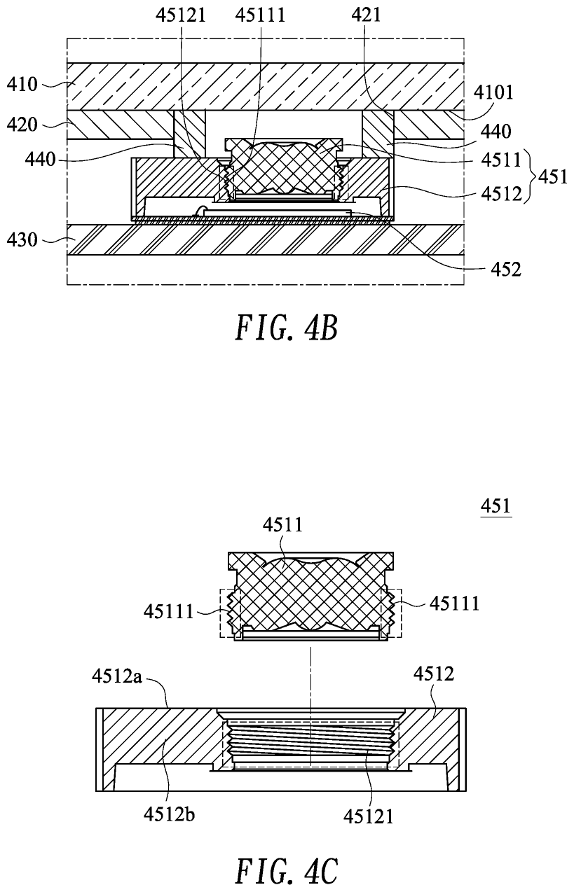

FIG. 4A is a schematic exploded view illustrating the indirect installation of a lens supporting element on a base structure through an interface structure according to a third embodiment of the present invention. FIG. 4B is a schematic cross-sectional view illustrating the assembled structure as shown in FIG. 4A. FIG. 4C is a schematic cross-sectional view illustrating the lens supporting element of the assembled structure as shown in FIG. 4B. As shown in FIGS. 4A to 4C, the electronic device 400 includes a display screen 410, an intermediate frame 420, a base structure 430, a foam structure 440, a lens supporting element 451 and a fingerprint sensing unit 452. The intermediate frame 420 includes a frame hollow region 421. The intermediate frame 420 is located beside a side 4101 of the display screen 410. The lens supporting element 451 is located near the frame hollow region 421. The lens supporting element 451 includes a lens barrel 4511 and a supporting structure 4512. Through the foam structure 440, the lens supporting element 451 and the fingerprint sensing unit 452 are positioned in the region between the intermediate frame 420 and the base structure 430.

In comparison with the above embodiments, the lens barrel 4511 and the supporting structure 4512 of this embodiment have corresponding threaded structures 45111 and 45121, respectively. The threaded structures 45111 and 45121 are engaged with each other. Consequently, the lens barrel 4511 is fixed in the upper part 4512a of the lens supporting element 451 and located near the frame hollow region 421. In other words, the lens barrel 4511 and the supporting structure 4512 are combined as the lens supporting element 451 through the engagement between the threaded structures 45111 and 45121.

In the above embodiments, some examples about the combination between the lens barrel and the supporting structure of the lens supporting element have been described. For example, the lens barrel and the supporting structure may be integrally formed as the lens supporting element. Alternatively, the unthreaded lens barrel and the supporting structure are directly combined with each other in a locking manner or a sheathing manner. Alternatively, the threaded lens barrel and the threaded supporting structure are directly combined with each other. It is noted that the way of combining the lens barrel and the supporting structure may be varied according to the practical requirements.

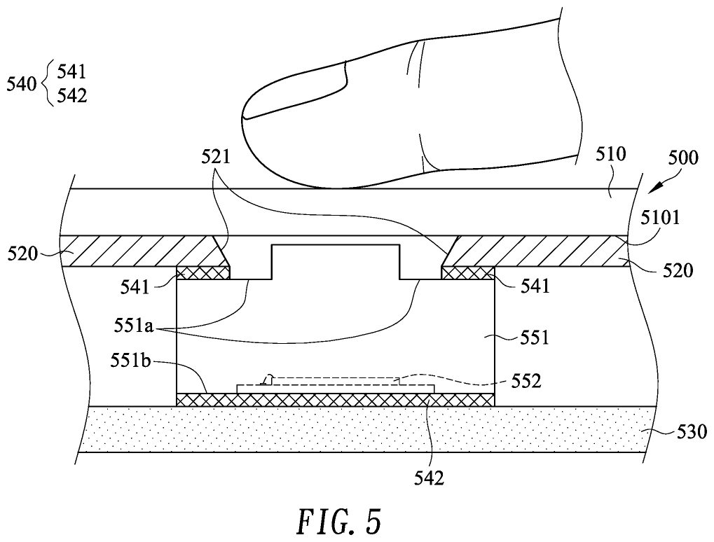

FIG. 5 is a schematic cross-sectional view illustrating the indirect installation of a lens supporting element on a base structure through an interface structure according to a fourth embodiment of the present invention. As shown in FIG. 5, the electronic device 500 includes a display screen 510, an intermediate frame 520, a base structure 530, an interface structure 540, a lens supporting element 551 and a fingerprint sensing unit 552. The intermediate frame 520 includes a frame hollow region 521. The interface structure 540 includes a first interface part 541 and a second interface part 542. The interface parts 541 and 542 are light-shielding structures, glue structure, elastic structures or injection molding structures (e.g., adhesives or foam structures). In this embodiment, the lens supporting element 551 is clamped between the intermediate frame 520 and the base structure 530 through the interface structure 540. The structure of the lens supporting element 551 will not be redundantly described herein. The structure of the lens supporting element 551 is similar to one of the above embodiments.

Please refer to FIG. 5 again. From top to bottom, the display screen 510, the intermediate frame 520, the first interface part 541, the lens supporting element 551, the fingerprint sensing unit 552, the second interface part 542 and the base structure 530 are sequentially arranged. The lens supporting element 551 is located near the frame hollow region 521. The first interface part 541 is arranged between the intermediate frame 520 and the lens supporting element 551 (i.e., the upper part 551a of the lens supporting element 551). The second interface part 542 is arranged between the lens supporting element 551 (i.e., the lower part 551b of the lens supporting element 551) and the base structure 530. In addition, the lens supporting element 551 is indirectly clamped between the intermediate frame 520 and the base structure 530 through the first interface part 541 and the second interface part 542, and not contacted with the intermediate frame 520 and the base structure 530.

In other words, the process of installing the lens supporting element 551 in the electronic device 500 may be described as follows. After the lens supporting element 551 is clamped between the intermediate frame 520 and the base structure 530, the first interface part 541 and the second interface part 542 (e.g., adhesives or foam structures) are arranged between the intermediate frame 520 and the lens supporting element 551 and/or between the lens supporting element 551 and the base structure 530. Consequently, the lens supporting element 551 is not directly contacted with the intermediate frame 520 and/or the base structure 530. In addition, the lens supporting element 551 is elastically contacted between the intermediate frame 520 and the base structure 530. Since the influence of the collision is reduced, the fingerprint sensing unit 552 within the lens supporting element 551 will not be damaged.

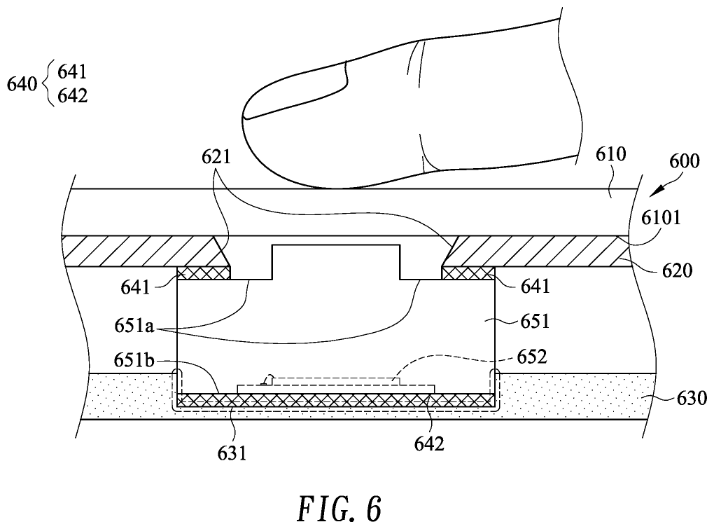

FIG. 6 is a schematic cross-sectional view illustrating the indirect installation of a lens supporting element on a base structure through an interface structure according to a fifth embodiment of the present invention. As shown in FIG. 6, the electronic device 600 includes a display screen 610, an intermediate frame 620, a base structure 630, an interface structure 640, a lens supporting element 651 and a fingerprint sensing unit 652. The intermediate frame 620 includes a frame hollow region 621. The interface structure 640 includes a first interface part 641 and a second interface part 642. The first interface part 641 and the second interface part 642 are light-shielding structures, glue structure, elastic structures or injection molding structures (e.g., adhesives or foam structures).

In comparison with the above embodiment, the base structure 630 further comprises a concave region 631. For example, the concave region 631 is an installation region of components, or an opening or a recess corresponding to the outer periphery of the intermediate frame. Moreover, a portion of the lens supporting element 651 and the fingerprint sensing unit 652 are combined with and accommodated within the concave region 631.

For example, a portion of the lens supporting element 651 (i.e., the lower part 651b of the lens supporting element 651) and the fingerprint sensing unit 652 are firstly combined with or fixed in the concave region 631 of the base structure 630. Especially, the portion of the lens supporting element 651 and the fingerprint sensing unit 652 are firstly combined with or fixed in the concave region 631 through the second interface part 642 in an adhering manner. Then, the lens supporting element 651 (i.e., the upper part 651b of the lens supporting element 651) is indirectly contacted with or elastically sustained against the intermediate frame 620 through the first interface part 641. Moreover, the lens supporting element 651 is located near the frame hollow region 621 or located under the frame hollow region 621. Consequently, the lens supporting element 651 is elastically clamped between the intermediate frame 620 and the base structure 630 through the interface parts 641 and 642, and not directly contacted with the intermediate frame 620 and the base structure 630. In such way, the overall thickness of the electronic device 600 with the lens supporting element 651 is effectively reduced.

In the above embodiments, the lens supporting element is combined with or positioned in the region between the intermediate frame and the base structure through the interface structure. It is noted that the examples of the interface structure are not restricted. For example, the interface structure may be a fastening member or an additional threaded structure. Consequently, the lens supporting element is combined with one of the intermediate frame and the base structure through the interface structure, and the lens supporting element is installed, embedded or positioned on one of the intermediate frame and the base structure. For example, the lens supporting element is tightened into the intermediate frame or the base structure through screws. Alternatively, the lens supporting element is combined with the intermediate frame or the base structure through an injection molding structure. For example, the injection molding structure is a hot melt post.

In the embodiments of FIG. 7A to FIG. 9C, the lens supporting element is positioned in the intermediate frame through the interface structure.

FIG. 7A is a schematic exploded view illustrating the indirect installation of a lens supporting element on an intermediate frame through an interface structure according to a first embodiment of the present invention. FIG. 7B is a schematic perspective view illustrating the assembled structure as shown in FIG. 7A. FIG. 7C is a schematic cross-sectional view illustrating the electronic device as shown in FIG. 7B. As shown in FIGS. 7A to 7C, the electronic device 700 includes a display screen 710, an intermediate frame 720, an interface structure 740, a lens supporting element 751 and a fingerprint sensing unit 752. The lens supporting element 751 has screw holes 751a. The intermediate frame 720 includes a frame hollow region 721 and a concave region 722. The frame hollow region 721 is located in the concave region 722. The interface structure 740 includes an interface part 741, a fastening member 742 and position-limiting elements 743. For example, the interface part 741 is an adhesive 741 or a foam structure 741. In this embodiment, the interface part 741 is a foam structure 741. The fastening member 742 includes an iron element 7421 and screws 7422. An example of the position-limiting element 743 is a nut structure 743.

The associated components will be described in more details. As shown in FIGS. 7A to 7C, the display screen 710 is located at the bottommost position of the electronic device 700. From bottom to top, the intermediate frame 720, the adhesive 741, the lens supporting element 751, the fingerprint sensing unit 752 and the fastening member 742 are sequentially arranged. The intermediate frame 720 is combined with the display screen 710 and located beside a side 7101 of the display screen 710. The nut structures 743 are formed in the intermediate frame 720 and located near the concave region 722. The adhesive 741 is disposed in the concave region 722. In an embodiment, the adhesive 741 has an opening corresponding to the frame hollow region 721. Alternatively, the concave region 722 is partially covered by the adhesive 741. An assembling method will be described as follows. Firstly, the lens supporting element 751 with the screw holes 751a and the fingerprint sensing unit 752 are covered or received by the iron element 7421. Then, the screws 7422 are sequentially penetrated through the iron element 7421, the corresponding screw holes 751a of the lens supporting element 751 and the corresponding nut structures 743 of the intermediate frame 720. Consequently, the lens supporting element 751 and the fingerprint sensing unit 752 are positioned within the iron element 7421, and indirectly contacted with or elastically sustained against the concave region 722. Meanwhile, the lens supporting element 751 and the fingerprint sensing unit 752 are indirectly installed in the intermediate frame 720. Since the lens supporting element 751 and the intermediate frame 720 are separated from each other through the adhesive 741 and the iron element 7421 and a portion of the lens supporting element 751 is disposed within the concave region 722, the overall thickness of the combined structure is reduced.

The electronic device 700 further comprises a base structure (not shown). The base structure is similar to the structures of the above embodiment, and not redundantly described herein.

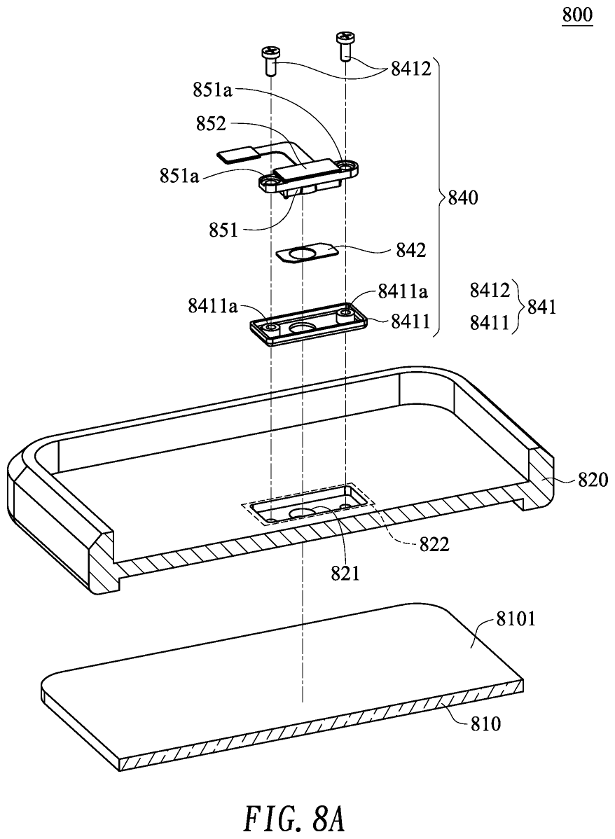

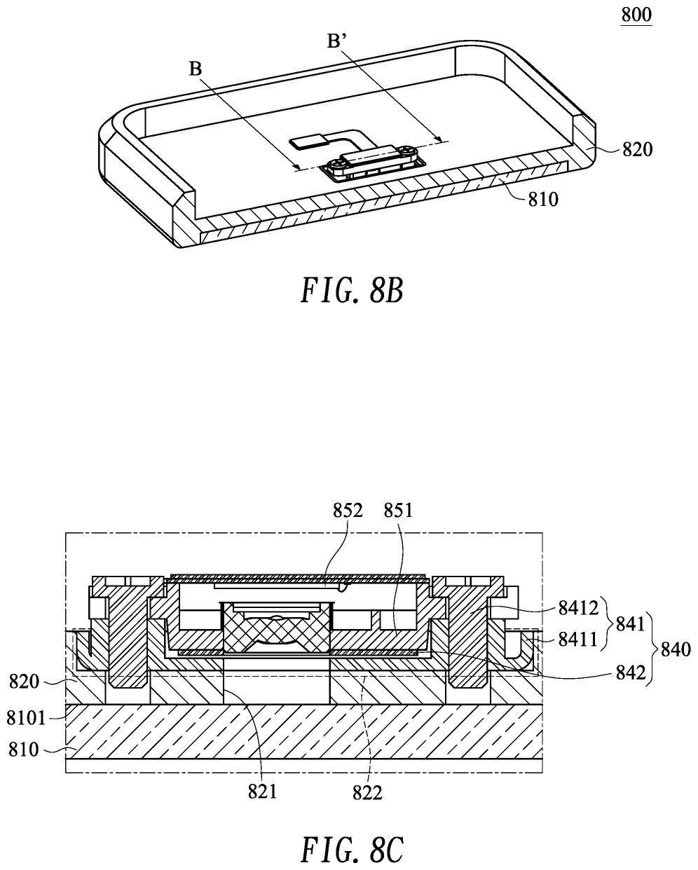

FIG. 8A is a schematic exploded view illustrating the indirect installation of a lens supporting element on an intermediate frame through an interface structure according to a second embodiment of the present invention. FIG. 8B is a schematic perspective view illustrating the assembled structure as shown in FIG. 8A. FIG. 8C is a schematic cross-sectional view illustrating the electronic device as shown in FIG. 8B. As shown in FIGS. 8A to 8C, the electronic device 800 includes a display screen 810, an intermediate frame 820, an interface structure 840, a lens supporting element 851 and a fingerprint sensing unit 852. The lens supporting element 851 has screw holes 851a. The intermediate frame 820 includes a frame hollow region 821 and a concave region 822. The frame hollow region 821 is located in the concave region 822. The interface structure 840 includes a fastening member 841 and an interface part 842. For example, the interface part 842 is an adhesive 842 or a foam structure 842. The fastening member 841 includes an iron element 8411 with screw holes 8411a and screws 8412.

The associated components will be described in more details. As shown in the drawings, the display screen 810 is located at the bottommost position of the electronic device 800. From bottom to top, the intermediate frame 820, the iron element 8411, the foam structure 842, the lens supporting element 851, the fingerprint sensing unit 852 and the screws 8412 are sequentially arranged. The intermediate frame 820 is combined with the display screen 810 and located beside a side 8101 of the display screen 810. The foam structure 842 is arranged between the iron element 8411 and the lens supporting element 851. An assembling method will be described as follows. Firstly, the screws 8412 are sequentially penetrated through the corresponding screw holes 851a of the lens supporting element 851 and the corresponding screw holes 8411a of the iron element 8411. Consequently, the lens supporting element 851 and the fingerprint sensing unit 852 are combined with the intermediate frame 820, and the lens supporting element 851 and the fingerprint sensing unit 852 are fixed in the concave region 822. That is, the lens supporting element 851 and the intermediate frame 820 are separated from each other through the iron element 8411 and the foam structure 842, and indirectly disposed within the intermediate frame 820.

The electronic device 800 further comprises a base structure (not shown). The base structure is similar to the structures of the above embodiment, and not redundantly described herein.

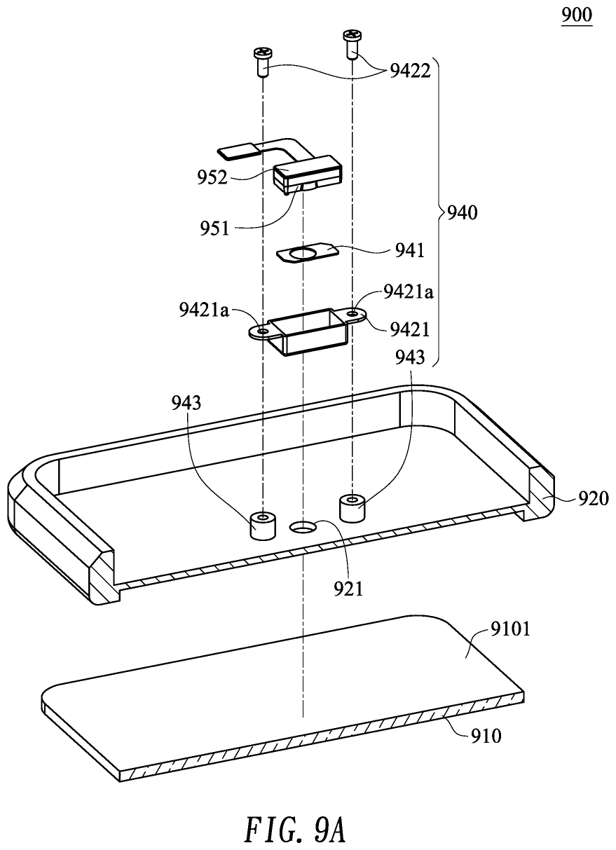

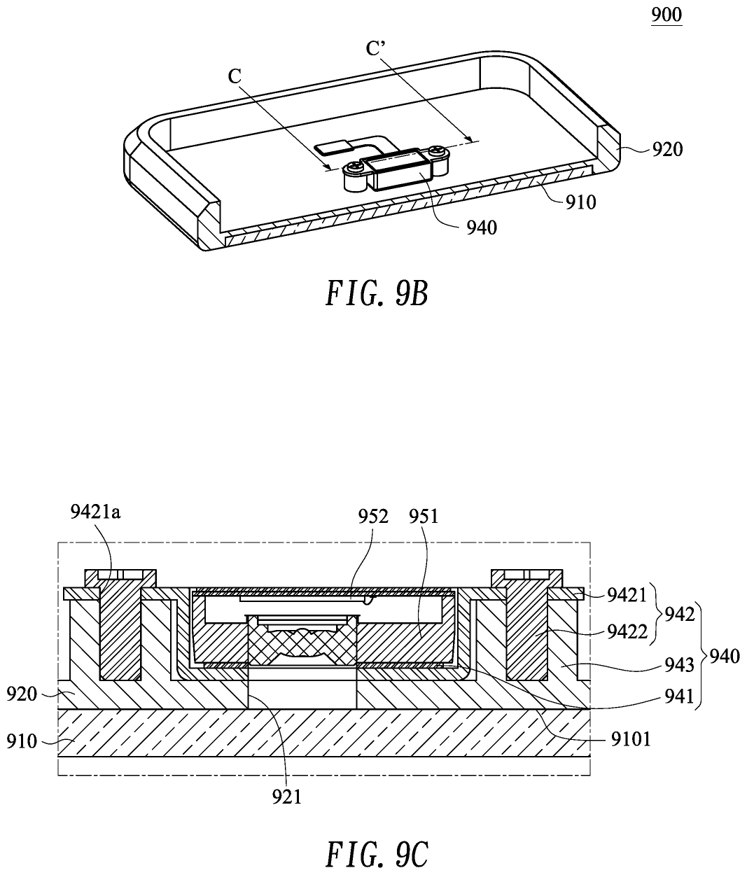

FIGS. 9A to 9C are schematic cross-sectional views illustrating the indirect installation of a lens supporting element on an intermediate frame through an interface structure according to a third embodiment of the present invention. FIG. 9B is a schematic perspective view illustrating the assembled structure as shown in FIG. 9A. FIG. 9C is a schematic cross-sectional view illustrating the electronic device as shown in FIG. 9B. As shown in FIGS. 9A to 9C, the electronic device 900 includes a display screen 910, an intermediate frame 920, an interface structure 940 and a fingerprint sensing assembly 950. The intermediate frame 920 includes a frame hollow region 921. The interface structure 940 includes an interface part 941, a fastening member 942 and position-limiting elements 943. For example, the interface part 941 is an adhesive 941 or a foam structure 941. The fastening member 942 includes an iron element 9421 with screw holes 9421a and screws 9422. An example of the position-limiting element 943 is a nut structure 943. The fingerprint sensing assembly 950 comprises a lens supporting element 951 and a fingerprint sensing unit 952.

The associated components will be described in more details. As shown in the drawings, the display screen 910 is located at the bottommost position of the electronic device 900. From bottom to top, the intermediate frame 920, the adhesive 941, the iron element 9421, the lens supporting element 951, the fingerprint sensing unit 952 and the screws 9422 are sequentially arranged. The intermediate frame 920 is combined with the display screen 910 and located beside a side 9101 of the display screen 910. The nut structures 943 are disposed on the intermediate frame 920 and located near the frame hollow region 921. An assembling method will be described as follows. Firstly, the adhesive 941 is placed within the iron element 9421. Then, the lens supporting element 951 and the fingerprint sensing unit 952 are placed within the iron element 9421. Then, the screws 9422 are sequentially penetrated through the corresponding screw holes 9421a of the iron element 9421 and the corresponding nut structures 943 on the intermediate frame 920. Consequently, the lens supporting element 951 and the fingerprint sensing unit 952 are positioned within and elastically sustained against the iron element 9421, and indirectly assembled with the intermediate frame 920. Since the lens supporting element 951 and the intermediate frame 920 are separated from each other through the iron element 9421 the adhesive 941, the lens supporting element 951 and the intermediate frame 920 are not directly contacted with the intermediate frame 920.

The electronic device 900 further comprises a base structure (not shown). The base structure is similar to the structures of the above embodiment, and not redundantly described herein.

It is noted that numerous modifications and alterations may be made while retaining the teachings of the invention. Moreover, the structures and specifications of the components may be varied according to the practical requirements.

For example, in another embodiment, one of the intermediate frame and the base structure is equipped with a concave structure for positioning or receiving the entire or a portion of the lens supporting element and/or the fingerprint sensing unit. Alternatively, the base structure is a circuit board, a chassis or a battery for supporting or positioning the lens supporting element and the intermediate frame in the region under the frame hollow region. Alternatively, the interface structure includes an interface part, a fastening member and a position-limiting element. The interface part is a light-shielding structure, a glue structure, an elastic structure or an injection molding structure. The fastening member includes an iron element and screws. The position-limiting element is a nut structure or a coupling structure. The thickness of the iron element may be adjusted according to the practical requirements.

In an embodiment, the interface structure is arranged between the intermediate frame and the lens supporting element. Alternatively, the interface structure is arranged between the lens supporting element and the base structure. In an embodiment, the lens supporting element includes an integral structure of a lens barrel and a supporting structure. Alternatively, the lens supporting element includes a two-piece structure of a lens barrel and a supporting structure. The lens barrel and the supporting structure can be combined together in a threaded engaging manner, a locking manner or an embedding manner. Alternatively, the lens barrel and the supporting structure are separate components, wherein the lens barrel is disposed within the frame hollow region and the supporting structure is disposed on the base structure. In other words, the embodiments may be varied according to the practical requirements.

From the above descriptions, the present invention provides an electronic device with a lens supporting element. Through an interface structure, the lens supporting element is directly or indirectly installed on a base structure, or indirectly installed on an intermediate frame, or clamped between the intermediate frame and the base structure. In some embodiments, the lens supporting element and a fingerprint sensing unit are assembled as a fingerprint sensing assembly. Consequently, the convenience of installing the fingerprint sensing assembling in the electronic device and the sensing quality of the fingerprint sensing unit are effectively enhanced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. An electronic device, comprising:
a display screen;
an intermediate frame comprising a frame hollow region, wherein the intermediate frame is located beside a side of the display screen;
a lens supporting element, wherein a fingerprint sensing unit is installed on the lens supporting element, and the fingerprint sensing unit is located near the frame hollow region and located beside the side of the display screen through the lens supporting element;
an interface structure; and
a base structure, wherein the lens supporting element is disposed on the base structure,
wherein the interface structure is arranged between the lens supporting element and one of the display screen and the intermediate frame, and/or the interface structure is arranged between the lens supporting element and the base structure.

2. The electronic device as claimed in claim 1, wherein the lens supporting element comprises a lens barrel and a supporting structure, wherein the lens barrel is arranged between an upper part of the supporting structure and the frame hollow region, and the interface structure is arranged between the supporting structure and one of the display screen and the intermediate frame and/or arranged between the supporting structure and the base structure.

3. The electronic device as claimed in claim 2, wherein the lens supporting element includes an integral structure of a lens barrel and a supporting structure, wherein the lens supporting element is adhered on the intermediate frame or the base structure, indirectly contacted with the intermediate frame or the base structure or clamped between the intermediate frame and the base structure through the upper part or a lower part of the supporting structure and the interface structure.

4. The electronic device as claimed in claim 3, wherein the interface structure is one of a glue structure, an elastic structure, an injection molding structure and a fastening member.

5. The electronic device as claimed in claim 4, wherein the injection molding structure is a hot melt post, and the lens supporting element is installed on the base structure through the hot melt post.

6. The electronic device as claimed in claim 4, wherein the fastening member comprises an iron element and a screw, wherein the iron element is combined with the lens supporting element, and the screw is penetrated through one of the iron element and the supporting structure, so that the supporting structure is fixed on the base structure.

7. The electronic device as claimed in claim 3, wherein the interface structure includes a first interface part and a second interface part, wherein the first interface part is located near the lens barrel and arranged between the supporting structure and one of the display screen and the intermediate frame, and the second interface part is arranged between the supporting structure and the base structure.

8. The electronic device as claimed in claim 7, wherein the first interface part is one of a light-shielding structure and a glue structure, and the second interface part is one of a glue structure, an elastic structure, an injection molding structure and a fastening member.

9. The electronic device as claimed in claim 8, wherein the injection molding structure is a hot melt post, and the supporting structure is installed on the base structure through the hot melt post.

10. The electronic device as claimed in claim 8, wherein the fastening member comprises an iron element and a screw, wherein the iron element is combined with the supporting structure, and the screw is penetrated through one of the iron element and the supporting structure, so that the supporting structure is fixed on the base structure.

11. The electronic device as claimed in claim 2, wherein the supporting structure is adhered on the intermediate frame or the base structure, indirectly contacted with the intermediate frame or the base structure or clamped between the intermediate frame and the base structure through the upper part or a lower part of the supporting structure and the interface structure.

12. The electronic device as claimed in claim 11, wherein the lens barrel and the supporting structure are combined together in a threaded engaging manner, a locking manner or an embedding manner, and the supporting structure is adhered on or indirectly contacted with the base structure through the interface structure.

13. The electronic device as claimed in claim 11, wherein the interface structure includes a first interface part and a second interface part, wherein the first interface part is located near the lens barrel and arranged between the supporting structure and one of the display screen and the intermediate frame, and the second interface part is arranged between the supporting structure and the base structure.

14. The electronic device as claimed in claim 13, wherein the first interface part is one of a light-shielding structure and a glue structure, and the second interface part is one of a glue structure, an elastic structure, an injection molding structure and a fastening member.

15. The electronic device as claimed in claim 14, wherein the injection molding structure is a hot melt post, and the supporting structure is installed on the base structure through the hot melt post.

16. The electronic device as claimed in claim 14, wherein the fastening member comprises an iron element and a screw, wherein the iron element is combined with the supporting structure, and the screw is penetrated through one of the iron element and the supporting structure, so that the supporting structure is fixed on the base structure.

17. The electronic device as claimed in claim 2, wherein the interface structure includes a first interface part and a second interface part, wherein the lens barrel is positioned in the frame hollow region through the first interface part, and the second interface part is arranged between the supporting structure and the base structure.

18. The electronic device as claimed in claim 17, wherein the first interface part is one of a light-shielding structure and a glue structure, and the second interface part is one of a glue structure, an elastic structure, an injection molding structure and a fastening member.

19. The electronic device as claimed in claim 18, wherein the injection molding structure is a hot melt post, and the supporting structure is installed on the base structure through the hot melt post.

20. The electronic device as claimed in claim 18, wherein the fastening member comprises an iron element and a screw, wherein the iron element is combined with the supporting structure, and the screw is penetrated through one of the iron element and the supporting structure, so that the supporting structure is fixed on the base structure.

21. The electronic device as claimed in claim 1, wherein one of the intermediate frame and the base structure comprises a concave region, and a portion of the lens supporting element is received within the concave region.

22. The electronic device as claimed in claim 1, wherein the base structure is one of a circuit board, a chassis and a battery.

23. The electronic device as claimed in claim 1, wherein the interface structure includes a first interface part and a second interface part, wherein the first interface part is located near the lens barrel and arranged between the lens supporting element and one of the display screen and the intermediate frame, and the second interface part is arranged between the lens supporting element and the base structure.

24. The electronic device as claimed in claim 23, wherein the first interface part is one of a light-shielding structure and a glue structure, and the second interface part is one of a glue structure, an elastic structure, an injection molding structure and a fastening member.

25. The electronic device as claimed in claim 24, wherein the injection molding structure is a hot melt post, and the lens supporting element is installed on the base structure through the hot melt post.

26. The electronic device as claimed in claim 24, wherein the fastening member comprises an iron element and a screw, wherein the iron element is combined with the lens supporting element, and the screw is penetrated through one of the iron element and the lens supporting element, so that the lens supporting element is fixed on the base structure.

27. An electronic device, comprising:
a display screen;
an intermediate frame comprising a frame hollow region, wherein the intermediate frame is located beside a side of the display screen;
a lens supporting element, wherein a fingerprint sensing unit is installed on the lens supporting element, and the fingerprint sensing unit is located near the frame hollow region and located beside the side of the display screen through the lens supporting element;
a fastening member; and
a base structure located under the lens supporting element,
wherein the lens supporting element is indirectly installed on one of the intermediate frame and the base structure through the fastening member.

28. The electronic device as claimed in claim 27, wherein the fastening member is arranged between one of the intermediate frame and the base structure and the lens supporting element, or the lens supporting element is received within the fastening member and combined with one of the intermediate frame and the base structure.

29. The electronic device as claimed in claim 27, wherein the fastening member comprises an iron element and a screw, wherein the iron element is combined with the lens supporting element, and the screw is penetrated through one of the iron element and the lens supporting element, so that the lens supporting element is fixed on one of the intermediate frame and the base structure.

30. The electronic device as claimed in claim 29, wherein the lens supporting element comprises a lens barrel and a supporting structure, wherein the lens barrel is arranged between an upper part of the supporting structure and the frame hollow region, and the supporting structure is installed on one of the intermediate frame and the base structure through the fastening member.

31. The electronic device as claimed in claim 30, wherein the lens supporting element includes a two-piece structure of the lens barrel and the supporting structure, or the lens supporting element includes an integral structure of the lens barrel and the supporting structure.

32. The electronic device as claimed in claim 27, wherein the electronic device further comprises an interface part, wherein the interface structure is arranged between the lens supporting element and one of the display screen and the intermediate frame, and/or the interface part is arranged between the lens supporting element and the base structure.

33. The electronic device as claimed in claim 32, wherein the interface part is one of a glue structure, an elastic structure and an injection molding structure.

34. An electronic device, comprising:
a display screen;
an intermediate frame comprising a frame hollow region, wherein the intermediate frame is located beside a side of the display screen;
a lens supporting element, wherein a fingerprint sensing unit is installed on the lens supporting element, and the fingerprint sensing unit is located near the frame hollow region and located beside the side of the display screen through the lens supporting element;
a fastening member;
an interface part; and
a base structure located under the lens supporting element,
wherein the lens supporting element is indirectly installed on the intermediate frame through the fastening member, and the interface part is arranged between the lens supporting element and the base structure.

35. The electronic device as claimed in claim 34, wherein the fastening member comprises an iron element and a screw, wherein the iron element is combined with the lens supporting element, and the screw is penetrated through one of the iron element and the lens supporting element, so that the lens supporting element is fixed on the intermediate frame.

36. The electronic device as claimed in claim 35, wherein the fastening member is arranged between the intermediate frame and the lens supporting element, or the lens supporting element is received within the fastening member and then combined with the intermediate frame.

37. The electronic device as claimed in claim 34, wherein the lens supporting element comprises a lens barrel and a supporting structure, wherein the lens barrel is arranged between an upper part of the supporting structure and the frame hollow region, and the supporting structure is indirectly installed on the intermediate frame through the fastening member.

38. The electronic device as claimed in claim 37, wherein the lens supporting element includes a two-piece structure of the lens barrel and the supporting structure, or the lens supporting element includes an integral structure of the lens barrel and the supporting structure.

39. The electronic device as claimed in claim 34, wherein the interface part is one of a glue structure, an elastic structure and an injection molding structure
